(19) United States
(12) Patent Application Publication
(10) Pub. No.: US 2004/0253779 A1
(43) Pub. Date: Dec. 16, 2004

(54) Method for manufacturing a bipolar transistor using a CMOS process

(76) Inventor: Dae-wook Hong, Cheongju-shi (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/801,407

(22) Filed: Mar. 16, 2004

(30) Foreign Application Priority Data
Apr. 1, 2003 (KR) 2003-20475

(51) Int. Cl. H01L 21/8238; H01L 21/331

(52) U.S. Cl. 438/203; 438/202; 438/204

(57) ABSTRACT

A method of forming a bipolar junction transistor using a CMOS process that includes performing a high voltage deep well and drive-in process in a semiconductor substrate having a predetermined substructure; performing a local oxidation of silicon (LOCOS) process; performing an Nbase and Pbase process on the resulting structure; forming logic N well and P well and annealing the logic wells; forming a poly gate and sequentially forming NMOS/PMOS LDD source/drain; and forming N+/P+ source/drain, annealing the source/drain and sequentially performing a CONT˜PAD process.

### BACKGROUND

1. Field of the Invention

An improved method for manufacturing bipolar transistors is disclosed which uses a complementary metal oxide structure (CMOS) process. The resulting BJT may be employed in the design of integrated circuits (IC) as analog, power, radio frequency (RF) ICs, etc.

2. Description of the Related Art

Generally, bipolar junction transistors (BJT) are superior to metal oxide semiconductor transistors (MOS TR) from the standpoint of performance, speed and grain size. Thus, BJT's are widely used in the design of analog, power and RF ICs.

A process utilizing the merits of BJT and CMOS processes, such as a bipolar-CMOS-DMOS (BCD) process, is available which is a power integration technique for integrating a bipolar and CMOS device, a logic circuit portion, with a double diffused MOS (DMOS), and a power device. However, this process is disadvantageous in that the manufacturing cost is high due to complexity of the process. Specifically, the double-diffused metaloxide semiconductor (DMOS) provides a metal-oxide semiconductor field effect transistor (MOSFET) manufactured using a double diffusion process and is generally employed in manufacturing a high voltage power device. Its disadvantages are explained below with respect to FIGS. 1-2.

FIGS. 1a to 1b are sectional views illustrating a conventional method for manufacturing a conventional parasitic option bipolar transistor using a CMOS process.

As shown in FIG. 1a, a vertical structure in which a collector is configured on a P-type substrate and a base and an emitter are configured in a N-type well is shown (hereinafter “PNP type structure”).

Turning to FIG. 1b, a horizontal structure in which an emitter, a base and a collector are configured in a P-type well is shown (hereinafter “NPN type structure”).

Next, FIG. 2 is a flow chart explaining the conventional method for manufacturing a bipolar transistor by using a CMOS process. As shown therein, a high voltage deep well and drive-in process is performed in step S12. A local oxidation of silicon (LOCOS) process is performed in step S14. Next, a logic N well and a logic P well are formed and then the logic wells are annealed in steps S16 and S18. As an optional process, processes of poly-interpolyoxide-poly (PIP), hydrogen reduction polysilicon (HR-poly), etc can be performed in step S20.

Then, a poly gate is formed and NMOS/PMOS lightly dope drain (LDD) source/drain are sequentially formed in steps S22 and S24.

Next, N+/P+ source/drain is formed, the source/drain are then annealed, and then a continuous pad oxide (CONT˜PAD) process is performed in steps S26 to S30.

Therefore, in the conventional manufacturing of a BJT transistor using a CMOS process, a parasitic type BJT leads to lower gains, reduced stability and other characteristics. As a result, there is a problem in that the fields of application of the transistor are severely restricted.

### SUMMARY OF THE DISCLOSURE

Methods for manufacturing a bipolar junction transistor by using a CMOS transistor are disclosed which is capable of expanding the range of application of the transistors that have improved characteristics, process controllability, etc. as compared to a conventional parasitic BJT. The disclosed method includes performing a CMOS logic process and an Nbase and Pbase process using a general P-type wafer as a base.

The disclosed is capable of achieving very stable and improved BJT characteristics by performing the ion implantation, heat budget, etc. of an Nbase and a Pbase under appropriate conditions unlike a conventional parasitic option BJT.

One disclosed method comprises: performing a high voltage deep well and drive-in process in a semiconductor substrate having a predetermined substructure; performing a local oxidation of silicon (LOCOS) process; performing an Nbase and Pbase process on the resulting structure; forming logic N well and P well and annealing the logic wells; forming a poly gate and sequentially forming NMOS/PMOS LDD source/drain; and forming N+/P+ source/drain, annealing the source/drain and sequentially performing a CONT˜PAD process.

Another disclosed method comprises: performing a high voltage deep well and drive-in process in a semiconductor substrate having a predetermined substructure; performing a LOCOS process, then forming a NMOS well and a PMOS well, and then annealing the logic wells; forming a poly gate and sequentially forming an Nbase/Pbase; and forming NMOS/PMOS LDD source/drain, forming N+/P+ source/drain, annealing the source/drain and sequentially performing a CONT˜PAD process.

### BRIEF DESCRIPTION OF THE DRAWINGS

Other aspects of the disclosed methods will become apparent from the following description of certain disclosed embodiments with reference to the accompanying drawings wherein:

FIGS. 1a to 1b are sectional views explaining a conventional method for manufacturing a parasitic option bipolar transistor by using a CMOS process;

FIG. 2 is a process chart for explaining the conventional method for manufacturing a bipolar transistors described in FIGS. 1a and 1b;

FIG. 3 is a plan view illustrating a disclosed method for manufacturing a bipolar transistor by using a CMOS process;

FIGS. 4 and 5 are sectional views for explaining a disclosed method for manufacturing a bipolar transistor by using a CMOS process;

FIGS. 6a and 6b are flow diagrams for illustrating a disclosed method for manufacturing a bipolar transistor by using a CMOS process; and

FIG. 7 is a sectional view illustrating a semiconductor device having a merged structure of a CMOS logic and a high voltage and BJT device that are formed by the process according to the preferred embodiment of the present invention as shown in FIGS. 6a and 6b.

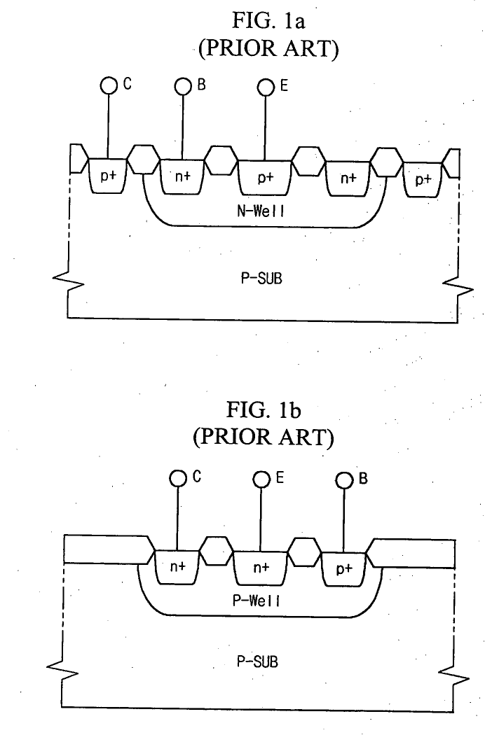

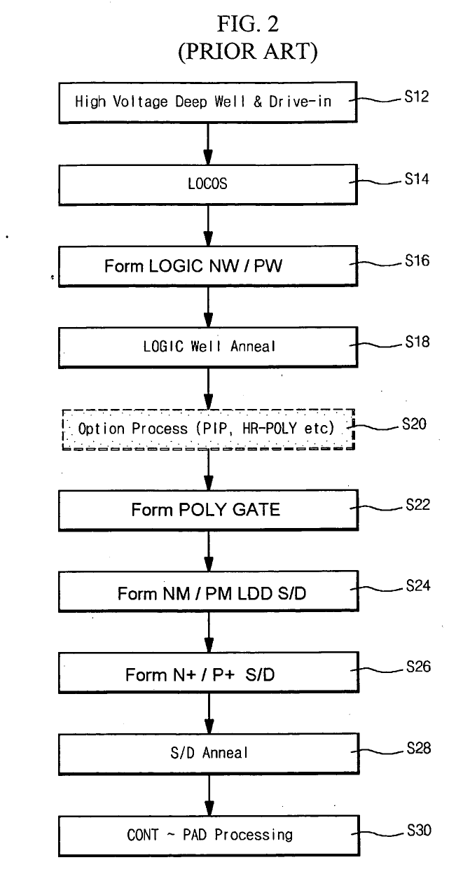

### DESCRIPTION OF THE PRESENTLY PREFERRED EMBODIMENTS

The following disclosed embodiments are for illustration only, and are not intended to limit the scope of this disclosure.

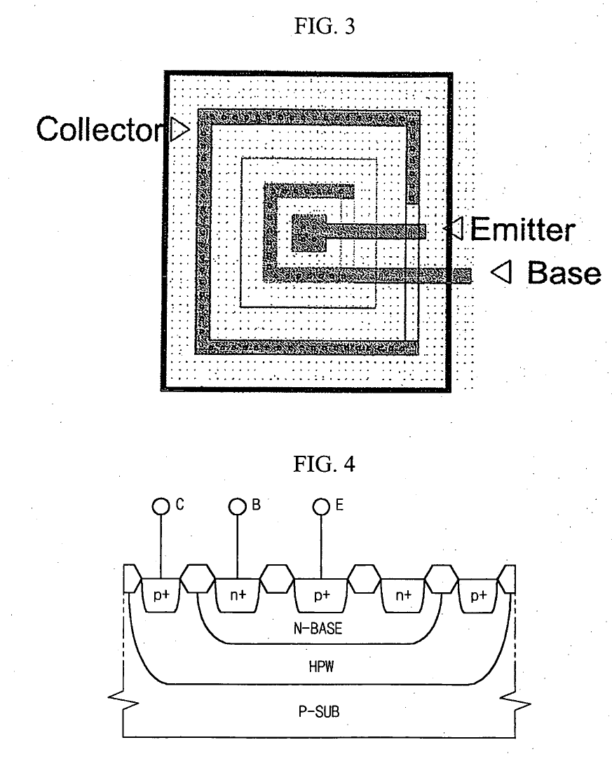

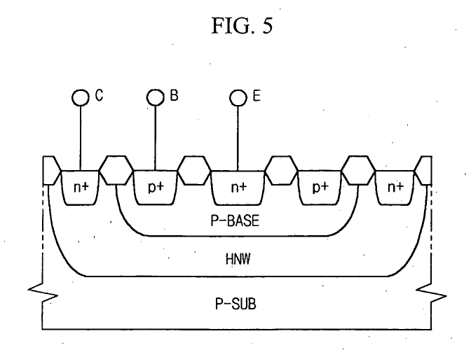

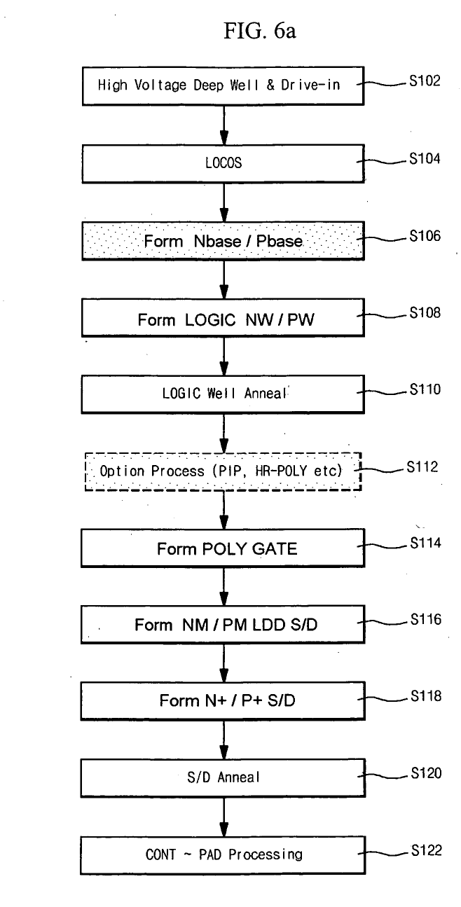

FIGS. 3 to 7 are plan views, a process chart and sectional views for explaining a disclosed method for manufacturing a bipolar transistor by using a CMOS process.

A collector is preferably used in a high deep junction well in which a high voltage process is employed. To a base, a retrograde implantation is performed and then the effect of a change in the width of the base is reduced by using the thermal budget of a logic well. And, at the same time, the process is integrated so as not to affect the standard logic process, thereby simplifying the process and improving the efficiency thereof. Further, an emitter is formed of a logic lightly doped drain (LOGIC LDD) and a N+ and P+ junction structure.

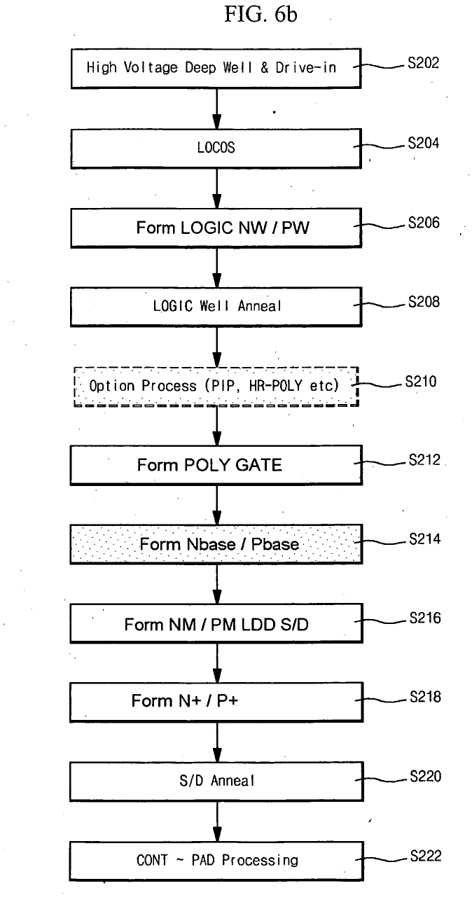

FIGS. 6a and 6b are process charts for explaining the method for manufacturing a bipolar transistor by using a CMOS process.

First, as shown in FIG. 6a, a high voltage deep well and drive-in process is performed at S102.

Continually, a local oxidation of silicon (LOCOS) process is performed at S104, and then an Nbase and Pbase process is performed at S106.

Next, a logic N well and a logic P well are formed and then the logic wells are annealed at S108 and S110 respectively.

As an optional process, processes of PIP, HR-poly, etc can be performed at S112.

Next, a poly gate is formed and NMOS/PMOS LDD source/drain are sequentially formed at S114 and S116 respectively.

Continually, N+/P+ source/drain is formed, then the source/drain are annealed, and then a CONT˜PAD process is performed in steps S118 to S122.

On the other hand, as shown in FIG. 6b, a high voltage deep well and drive-in process is performed at S202.

Continually, a LOCOS process is performed at S204, and a process of forming a NMOS well and a PMOS well is performed at S106.

Next, the logic wells are annealed at S208.

As an optional process, processes of PIP, HR-poly, etc can be performed at S210.

Next, a poly gate is formed and an Nbase and a Pbase are sequentially formed at S212 and S214 respectively.

Continually, a NMOS/PMOS LDD source/drain are formed, then N+/P+ source/drain are formed, then the source/drain are annealed, and then a CONT˜PAD process is sequentially performed at S216 to S222.

As shown in FIG. 6b, the disclosed process can reduce the effects of the change in the width of the Nbase caused by an optional process such as PIP, HR-poly, etc. at S210, thereby improving the characteristics sensitive to a change in base width and the uniformity characteristics of a BJT device.

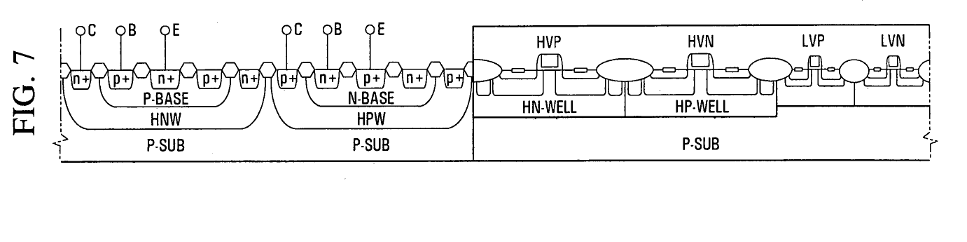

FIG. 7 is a sectional view illustrating a semiconductor device having a merged structure of a CMOS logic and a high voltage and BJT device that are formed by the disclosed process as illustrated in FIGS. 6a and 6b.

As seen from above, the disclosed methods can achieve improved BJT characteristics as compared to a conventional parasitic BJT using a CMOS process which is capable of bringing out a shift in the characteristics of a MOS transistor as well as the characteristics of the BJT when a change in the characteristics of the parasitic BJT is needed, and can obtain a desired gain and characteristics of the main parameters according to a base setting condition.

Consequently, the present invention is capable of expanding the range of application with the improvement of BJT characteristics and is employable for anplification, power, RF ICs, etc.

Further, by employing the CMOS process as a basic process, it is possible to drastically reduce manufacturing costs as compared to the BCD process from the viewpoint of process integration.

The forgoing embodiment is merely exemplary and is not to be construed as limiting of this disclosure. The present teachings can be readily applied to other types of apparatuses. The detailed description is intended to be illustrative, and not to limit the scope of the claims. Many alternatives, modifications, and variations will be apparent to those skilled in the art.

What is claimed is:

1. A method for manufacturing a bipolar transistor by using a CMOS process, comprising:
performing a high voltage deep well and drive-in process on a semiconductor substrate;
performing a local oxidation of silicon (LOCOS) process;
performing an Nbase and Pbase process;
forming logic N well and P well and annealing the logic wells;
forming a poly gate and sequentially forming NMOS/PMOS LDD source/drain; and
forming N+/P+ source/drain, annealing the source/drain and sequentially performing a CONT˜PAD process.

2. The method of claim 1 further comprising performing a PIP process after the step of forming the poly gate.

3. The method of claim 1 further comprising performing a HR-poly process after the step of forming the poly gate.

4. The method of claim 2 further comprising sequentially forming a NMOS/PMOS LDD source/drain.

5. The method of claims 3 further comprising sequentially forming a NMOS/PMOS LDD source/drain.

6. A method for manufacturing a bipolar transistor by using a CMOS process comprising:
performing a high voltage deep well and drive-in process on a semiconductor substrate;
sequentially performing a local oxidation of silicon (LOCOS) process forming an NMOS well and a PMOS well, and then annealing the logic wells;
forming a poly gate and sequentially forming an Nbase/Pbase; and
sequentially forming NMOS/PMOS source/drain, forming N+/P+ source/drain, annealing the source/drain and sequentially performing a CONT˜PAD process.

7. The method of claim 5 further comprising performing a PIP process before the forming of the poly gate.

8. The method of claim 5 further comprising performing a HR-poly process before the forming of the poly gate.

9. The method of claim 7 further comprising sequentially forming a Nbase and Pbase.

10. The method of claim 8 further comprising sequentially forming a Nbase and Pbase
